(19) United States
(12) Patent Application Publication
(10) Pub. No.: US 2008/0238261 A1
(43) Pub. Date: Oct. 2, 2008

(54) Piezoelectric element and its manufacturing method

(75) Inventors: Koji Ohashi, Chino-shi (JP); Akio Konishi, Shiojiri-shi (JP)

Correspondence Address: Edwards Angell Palmer & Dodge LLP, P.O. Box 55874, Boston, MA, 02205, US

(73) Assignee: Seiko Epson Corporation, Tokyo (JP)

(21) Appl. No.: 12/080,010

(22) Filed: Mar. 31, 2008

(30) Foreign Application Priority Data
Mar. 29, 2007 (JP) 2007-087576

(51) Int. Cl. H01L 41/08; H01L 41/22

(52) U.S. Cl. 310/340; 427/100

(57) ABSTRACT

A piezoelectric element includes: a base substrate; a lower electrode provided on the base substrate; a piezoelectric layer provided on the lower electrode; an upper electrode provided on the piezoelectric layer; and a protection layer that covers a side surface of the piezoelectric layer, wherein the protection layer is formed from polymeric material.

The entire disclosure of Japanese Patent Application No. 2007-087576, filed Mar. 29, 2007 is expressly incorporated by reference herein.

### BACKGROUND

1. Technical Field

The present invention relates to piezoelectric elements, and methods for manufacturing the same.

2. Related Art

In general, piezoelectric elements have a structure in which a piezoelectric composed of inorganic oxide is interposed between two electrodes. The piezoelectric element is capable of electromechanical conversion in which deformation is generated in the piezoelectric by applying an electric filed across the electrodes. The piezoelectric expands and contracts according to electrical signals applied through the electrodes. Polycrystal sintered materials such as lead zirconate titanate (PZT) may be representative as the piezoelectric materials. The thickness of the piezoelectric layer is generally set to 500 nm -1500 nm in order to maintain its mechanical reliability. When an operation voltage is applied across the electrodes with such a piezoelectric layer being interposed, the potential gradient generated in the piezoelectric layer becomes 100 kV/cm or more. Therefore the piezoelectric element needs a high insulation property. In order to prevent dielectric breakdown in the piezoelectric element, the leakage current at the time of application of an operation voltage should preferably be suppressed at 10⁻⁸ A or less.

One of the primary causes that increase the leakage current is moisture in the air-atmosphere that adheres to side surfaces of piezoelectric elements. When moisture in the air-atmosphere adheres to side surfaces of a piezoelectric element, it is possible that leakage current is generated as it runs along the side surfaces, which may eventually develop into dielectric breakdown. Te cope with this problem, methods of coating an oxide film or a nitride film as a protection film on side surfaces of piezoelectric layers to prevent moisture from adhering to the side surfaces have been attempted.

For example, JP-A-2003-143625 describes coating side surfaces of dielectric layers with aluminum oxide to protect the side surfaces from impurities such as moisture and hydrogen.

However, as protection films to prevent the dielectric from contacting impurities, materials having considerably large coefficient of elasticity, such as, aluminum oxide and the like are generally used. However, the protection films composed of such large coefficient of elasticity are not suitable for use in piezoelectric elements. In other words, when covered by such a hard material, operations of extension and contraction of piezoelectric layers are restricted, which may result in a problem of operation failure of piezoelectric elements.

### SUMMARY

In accordance with an advantage of some aspects of the invention, piezoelectric elements with reduced leakage current and reduced operation failures and methods for manufacturing the same are provided.

A piezoelectric element in accordance with an embodiment of the invention includes: a base substrate; a lower electrode provided on the base substrate; a piezoelectric layer provided on the lower electrode; an upper electrode provided on the piezoelectric layer; and a protection layer that covers a side surface of the piezoelectric layer, wherein the protection layer is formed from polymeric material.

Because the protection layer is provided on the piezoelectric element, leakage current is reduced, and because the protection layer is formed from polymeric material, operation failures of the piezoelectric layer can be reduced.

In the piezoelectric element in accordance with an aspect of the invention, the polymeric material may include at least one type of thermosetting resin, radiation setting resin, and modified products of the aforementioned resins.

In the piezoelectric element in accordance with an aspect of the invention, the polymeric material may include thermoplastic material or its modified product.

A method for manufacturing a piezoelectric element in accordance with an embodiment of the invention includes the steps of forming a lower electrode on a base substrate; successively laminating a piezoelectric layer and an upper electrode layer on the base substrate and the lower electrode; and coating a polymer precursor to cover at least an exposed surface of the piezoelectric layer, wherein the step of coating the polymer precursor is performed by a droplet jet method.

As a result, a piezoelectric element with reduced leakage current and reduced operation failure of the piezoelectric can be manufactured.

The method for manufacturing a piezoelectric element in accordance with an aspect of the invention may further include a heat treatment step of heating the polymer precursor to be changed to polymeric material.

The method for manufacturing a piezoelectric element in accordance with an aspect of the invention may further include a radiation treatment step of applying radiation to the polymer precursor to be changed to polymeric material.

### BRIEF DESCRIPTION OF THE DRAWINGS

FIG. 1 is a schematic cross-sectional view of a piezoelectric element 100 in accordance with an embodiment of the invention.

FIG. 2 is a schematic cross-sectional view of the piezoelectric element 100 in accordance with the embodiment of the invention.

FIG. 3 is a schematic plan view of the piezoelectric element 100 in accordance with the embodiment of the invention.

FIG. 4 is a schematic cross-sectional view showing a step of a method for manufacturing a piezoelectric element 100 in accordance with an embodiment of the invention.

FIG. 5 is a schematic cross-sectional view showing a step of the method for manufacturing a piezoelectric element 100 in accordance with an embodiment of the invention.

FIG. 6 is a schematic cross-sectional view showing a step of the method for manufacturing a piezoelectric element 100 in accordance with an embodiment of the invention.

FIG. 7 is a schematic cross-sectional view showing a step of the method for manufacturing a piezoelectric element 100 in accordance with an embodiment of the invention.

FIG. 8 is a schematic cross-sectional view showing a step of the method for manufacturing a piezoelectric element 100 in accordance with an embodiment of the invention.

FIG. 9 is a graph showing results of current-voltage measurement as reference examples.

### DESCRIPTION OF EXEMPLARY EMBODIMENTS

Preferred embodiments of the invention are described below with reference to the accompanying drawings. It is noted that the embodiment described below is an example of the invention.

1. Piezoelectric Element

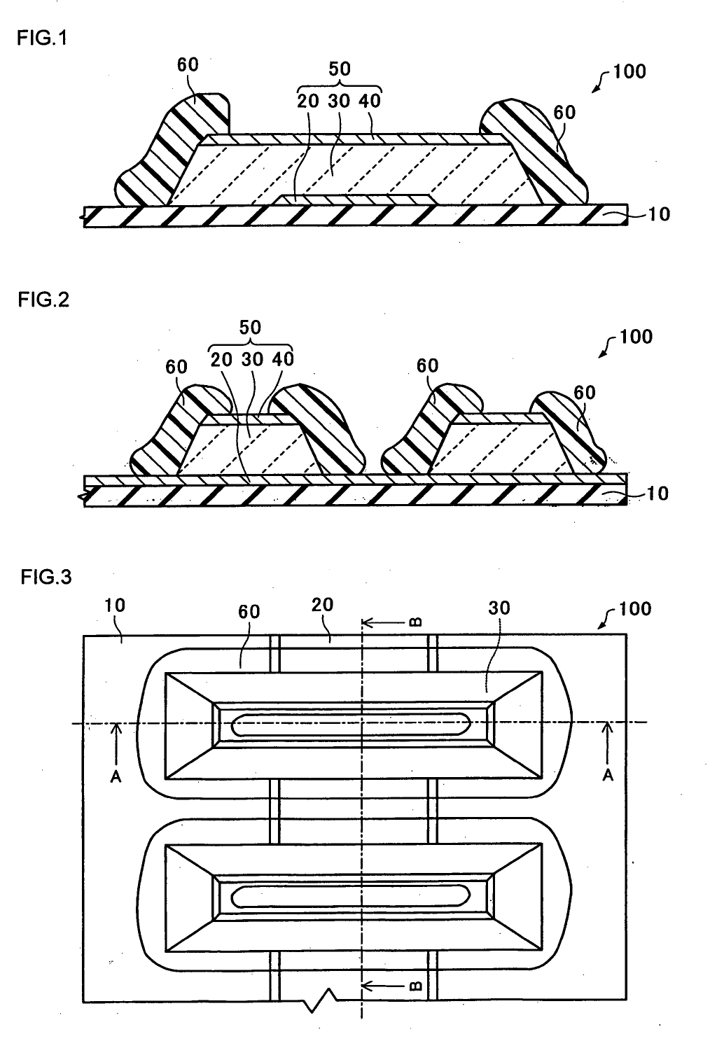

FIG. 1 is a schematic cross-sectional view of a piezoelectric element 100 in accordance with an embodiment of the invention. FIG. 2 is a schematic cross-sectional view of the piezoelectric element 100 in accordance with the embodiment of the invention. FIG. 3 is a schematic plan view of the piezoelectric element 100 in accordance with the embodiment of the invention. FIG. 1 and FIG. 2 are cross-sectional views taken along a line A-A and a line B-B of FIG. 3, respectively.

The piezoelectric element 100 includes a base substrate 10, a lower electrode 20, a piezoelectric layer 30, an upper electrode 40 and a protection layer 60.

The base substrate 10 is a member that provides mechanical outputs when the piezoelectric element 100 is operated. The base substrate 10 may include, for example, a vibration plate, thereby functioning as a movable part of the liquid jet head, or may form a part of a wall of a pressure generation chamber. The thickness of the base substrate 10 may be optimally selected according to the coefficient of elasticity of the material used and the like. The base substrate 10 is capable of warping and vibrating by the operation of the piezoelectric layer 30. The material for the base substrate 10 may preferably include a material having high rigidity and mechanical strength. As the material for the base substrate 10, for example, inorganic oxides such as zirconium oxide, silicon nitride, silicon oxide and the like, and alloys such as stainless steel and the like, may preferably be used. The base substrate 10 may have a laminate structure of layers of two or more materials.

As shown in FIG. 1 through FIG. 3, in accordance with the present embodiment, a portion including a part of the lower electrode 20, the piezoelectric layer 30 and the upper electrode 40 is referred to as a capacitor structure 50. The piezoelectric element 100 may include a plurality of capacitor structures 50, as shown in FIG. 2.

The lower electrode 20 is formed on the base substrate 10. The lower electrode 20 may have any appropriate thickness in the range in which deformation in the piezoelectric layer 30 can be transmitted to the base substrate 10. The lower electrode 20 pairs with the upper electrode 40 to function as one of the electrodes that interpose the piezoelectric layer 30. The lower electrode 20 may be formed commonly with the lower electrode 20 of the next capacitor structure 50, for example, as shown in FIG. 3. The lower electrode 20 is electrically connected to an external circuit not shown. The thickness of the lower electrode 20 may be, for example, between 100 nm and 300 nm. The lower electrode 20 may be formed from any material, without any particular limitation. For example, a variety of metals such as titanium, gold, nickel, iridium, platinum and the like, conductive oxides of the aforementioned metals (for example, iridium oxide), strontium ruthenium complex oxide, lanthanum nickel complex oxide and the like may be used. Also, the lower electrode 20 may be in a single layer of any of the materials, or in a laminate structure of layers of a plurality of the materials exemplified above.

The piezoelectric layer 30 is provided on the base substrate 10 and the lower electrode 20. The thickness of the piezoelectric layer 30 may be 500 nm to 1500 nm. Upon application of an electric field by the lower electrode 20 and the upper electrode 40, the piezoelectric layer 30 expands or contracts by its deformation, thereby warping or vibrating the base substrate 10. The piezoelectric layer 30 may be formed from a material having piezoelectricity. As the material for the piezoelectric layer 30, perovskite type oxides expressed by a general formula ABO₃ (A includes Pb, and B includes Zr and Ti) are favorably used. For example, lead zirconate titanate (PZT) and lead zirconate titanate niobate (PZTN) have good piezoelectric performance, and therefore are preferable as the material for the piezoelectric layer 30.

The upper electrode 40 is provided on the piezoelectric layer 30. The thickness of the upper electrode 40 is not particularly limited within the range that does not adversely affect the operation of the piezoelectric element 10. The thickness of the upper electrode 40 may be, for example, between 50 nm and 200 nm. The upper electrode 40 pairs with the lower electrode 20 to function as the other of the electrodes of the piezoelectric element 100. The upper electrode 40 may be formed from any material having conductivity that satisfies the aforementioned functions, without any particular limitation. For example, as the material for the upper electrode 40, a variety of metals such as nickel, iridium, gold, titanium, platinum, and the like, conductive oxides of the aforementioned metals (for example, iridium oxide), strontium ruthenium complex oxide, lanthanum nickel complex oxide and the like may be used. Also, the upper electrode 40 may be in a single layer of any of the materials, or in a laminate structure of layers of a plurality of the materials exemplified above.

The protection layer 60 is provided in a manner to cover side surfaces of the piezoelectric layer 30. In the example shown in FIG. 1 through FIG. 3, the protection layer 60 is formed to cover side surfaces of the piezoelectric layer 30, a portion of the upper electrode 40, a portion of the lower electrode 20 and a portion of the base substrate 10. The protection layer 60 has a function to prevent the side surface of the piezoelectric layer 30 from deterioration caused by impurities including, hydrogen, water and compound containing carbon that may be diffused from outside into the piezoelectric layer 30. With this function, leakage current running along the side surfaces of the piezoelectric layer 30 can be reduced.

The protection layer 60 may be provided in a manner to cover surfaces of other members, other than the side surfaces of the piezoelectric layer 30. The protection layer 60 may preferably be provided in an amount as small as possible as long as the protection layer 60 covers the side surface of the piezoelectric layer 30, so as not to restrict operations of the piezoelectric element 100 as much as possible. Also, the protection layer 60 may preferably be provided in consideration of wirings to each of the electrodes of the piezoelectric element 100. The protection layer 60 may preferably be formed not to cover the central area on the upper surface of the upper electrode 40, like the example shown in FIG. 1 and FIG. 3, and may also be provided in a smallest amount possible on the base substrate 10 and the lower electrode 20.

The protection layer 60 may preferably have a thickness that does not cause an operation failure in the piezoelectric element 100. The thickness that causes fewer operation failures of the piezoelectric element 100 depends on the material of the protection layer 60. The protection layer 60 in accordance with the present embodiment is formed from polymeric material, and therefore Young's modulus of the protection layer 60 is as small as 1×10¹⁰ Pa or less. Therefore the thickness of the protection layer 60 can be 200 nm to 2000 nm in a thickness direction normal to the side surface of the protection layer 30. When the thickness is less than 200 nm, its function to prevent diffusion of impurities becomes insufficient, and when the thickness is greater than 2000 nm, the possibility of an operation failure of the piezoelectric element 100 would not be ignored.

The protection layer 60 may be provided by, for example, a droplet discharging method such as an ink jet method, a spin coat method or the like. When a spin coat method is used, the protection layer 60 may be provided over the entire top surface of the piezoelectric element 100, and patterning may be conducted if necessary. More preferably, the protection layer 60 may be provided by a droplet discharging method. By using the droplet discharging method, the protection layer 60 that covers the side surface of the piezoelectric layer 30 in a smallest amount can be formed.

The material for the protection layer 60 is polymeric material. The polymeric material for the protection layer 60 may preferably have gas-barrier property. However, even when the gas-barrier property is small, a wide range of materials can be selected as the thickness of the protection layer 60 can be made as much as about 2000 nm. Polymeric materials that can be selected as the material for the protection layer 60 are listed below.

The polymeric material for the protection layer 60 may or may not have a cross-linked structure. As the polymeric material having the cross-linked structure, one kind or a mixture of plural kinds selected from a group consisting of epoxy resin, polyimide resin, phenol resin, benzoguanamine resin, polyurethane resin, unsaturated polyester resin, allyl resin, fluororesin, epoxy acrylate resin, silicon resin, copolymers of the aforementioned materials, and derivative products or modified products of the aforementioned materials may be used. These resins may form the cross-linked structure with another compound included, such as, a hardening agent. Also, these resins may include compounds that add other functions which do not participate in skeleton reaction of the resins, such as, an anti-oxidation agent or the like. Moreover, these resins may include reaction products or reaction residues of compounds that participate in the bridging reaction of the resins.

Generally, heat or radiation may be applied to the polymeric material having the cross-linked structure to start or promote the reaction. For example, in the case of epoxy resin, the resin may be reacted with a monomeric compound containing a polyfunctional hardening agent such as diethylenetriamine or the like, thereby forming a three-dimensional cross-linked structure. Such a reaction is promoted by heat, and its product hardens, such that the resin is called a thermosetting resin. As the protection layer 60 in accordance with the present embodiment, not only the epoxy resin but also any of the other exemplified resins can be suitably used as a thermosetting resin. Also, radiation such as visible rays, ultraviolet rays, infrared rays or electron rays may be applied to the exemplified resin, whereby the reaction to form three-dimensional cross-linked structures can be promoted. For example, when light is irradiated to a monomer mixture containing a photopolymerization start agent such as an azo-compound, its hardening reaction is promoted. Resins that are hardened by irradiation of radiation are called radiation setting resins. Any of the exemplified resins may be mixed with a radiation polymerization start agent thereby being preferably used as a radiation setting resin for the protection layer 60.

Moreover, as the polymeric material for the protection layer 60, a thermoplastic resin without a cross-linked structure may be used. As the thermoplastic resin, one kind or a mixture of plural kinds selected from a group consisting of polyolefin, polyester, polyamide and polysaccharide, copolymers of the aforementioned materials, and derivative products or modified products of the aforementioned materials may be used. Specific examples of the thermoplastic resin include one kind or a mixture of multiple kinds selected from a group consisting of polyethylene, polypropylene, polybutadiene, polystyrene, polyvinyl alcohols, polyvinyl acetate, polyacrylonitrile, polymethylmethacrylate, polyvinyl chloride, polyvinylidene chloride, polyvinylidene fluoride, poly(tetrafluoroethylene), polyethylene terephthalate, copolymer of adipic acid and methylenediamine, ring-opening polymer of ε-caprolactam, copolymer of parafenirengeamin and terephthalic acid chloride, poly(p-phenylenebenzobisoxazole), cellulose, cellulose acetate, cellulose deacetate, and modified products of the aforementioned materials may be used. Each of the resins may be used alone or may include a compound that adds another function such as an anti-oxidation agent or the like.

The piezoelectric element 100 in accordance with the present embodiment has the following characteristics. Since deterioration of the piezoelectric of the piezoelectric layer 30 is suppressed, the piezoelectric element 100 has reduced leakage current, and since the protection layer 60 is formed from polymeric material, the piezoelectric element 100 has reduced operation failures. Also, when the piezoelectric element 100 is formed with the side surface of the piezoelectric layer 30 being covered by a minimum amount of the protection layer 60, operation failures of the piezoelectric element 100 can be further reduced.

2. Method for Manufacturing Piezoelectric Element

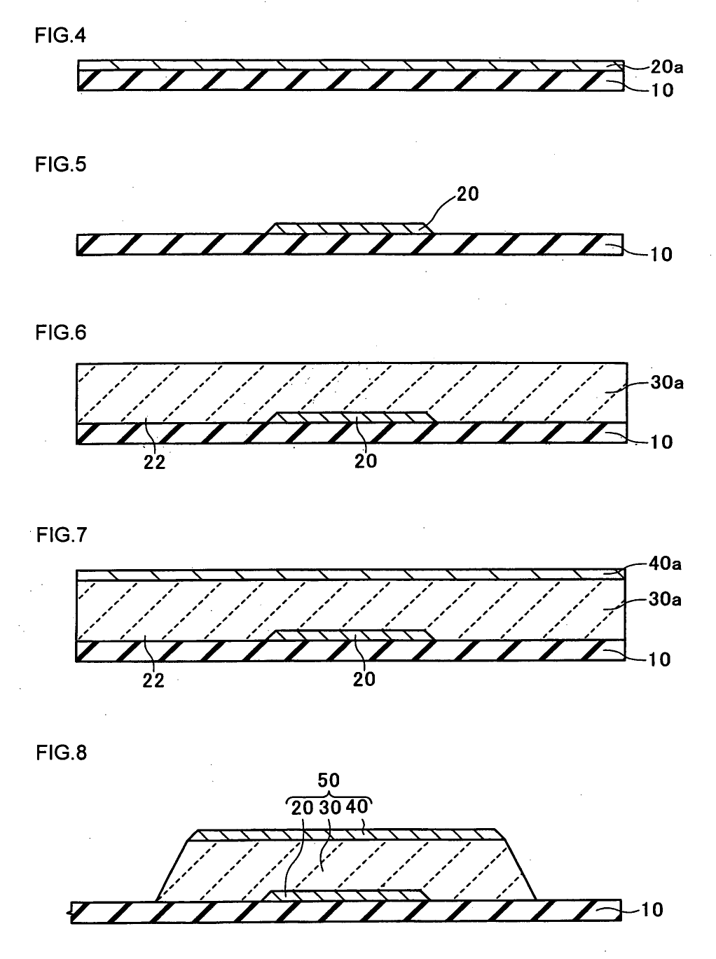

FIGS. 4 to 8 are schematic cross-sectional views showing steps of a method for manufacturing a piezoelectric element 100 shown in FIG. 1. FIGS. 4 through 8 show cross sections corresponding to a cross section taken along a line A-A in FIG. 3.

The method for manufacturing a piezoelectric element 100 in accordance with the present embodiment includes the steps of forming a lower electrode 20a, successively laminating a piezoelectric layer 30a and an upper electrode layer 40a, patterning the upper electrode layer 40a and the piezoelectric layer 30a, and coating a polymer precursor, wherein the step of coating a polymer precursor is performed by a droplet discharging method.

As shown in FIG. 4, first, a base substrate 10 is prepared, and a lower electrode layer 20a is formed on the base substrate 10. The lower electrode layer 20a may be formed by, for example, a sputter method, a vacuum deposition method, a CVD method or the like.

Next, as shown in FIG. 5, the lower electrode layer 20a is etched, thereby conducting a first patterning step to form a lower electrode 20. The etching of the lower electrode layer 20a may be performed by a photolithography method or the like.

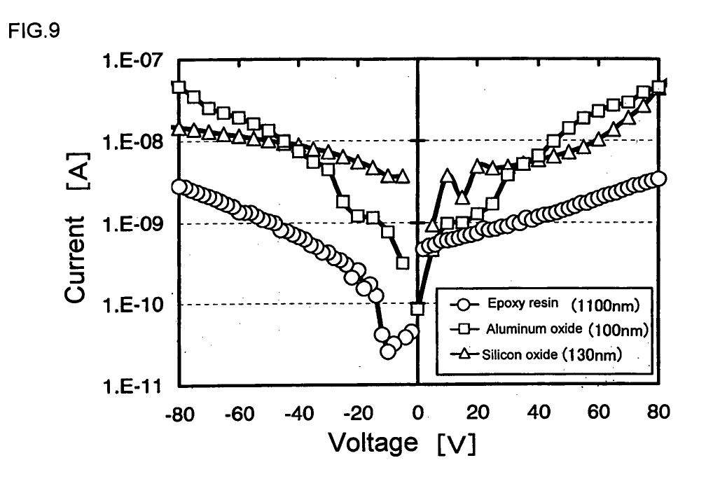

Next, as shown in FIG. 9, the step of successively laminating the piezoelectric layer 30a and the upper electrode layer 40a is performed. As shown in FIG. 6, the piezoelectric layer 30a is formed on the base substrate 10 and the lower electrode 20. The piezoelectric layer 30a may be formed by a sol-gel method, a CVD method, a sputter method or the like. In the sol-gel method, a series of the steps of coating and drying a source material, pre-heating, and annealing for crystallization may be repeated a plurality of times to obtain a desired film thickness. Next, as shown in FIG. 7, an upper electrode layer 40a is formed on the piezoelectric layer 30a. The upper electrode layer 40a may be formed by, for example, a sputter method, a vacuum deposition method, a CVD method or the like. It is noted that, after the step of forming the upper electrode layer 40a, annealing may be conducted again at a temperature higher than the crystallization annealing temperature. As a result, good interfaces can be formed between the upper electrode layer 40a and the piezoelectric layer 30.

Then, as shown in FIG. 8, at least the upper electrode layer 40a and the piezoelectric layer 30a are patterned, thereby forming a capacitor structure 50. This step may be conducted, using, for example, a photolithography method or the like, with masks formed. Also, in the present step, photolithography processes may be conducted a plurality of times. The etching in the present step may be conducted by using a known dry etching method or the like.

Then, to provide a protection layer 60 that covers the side surface of the piezoelectric layer 30 as shown in FIG. 1 through FIG. 3, the step of coating a polymer precursor is conducted. The polymer precursor is provided, using a droplet discharging method. The droplet discharging method may be represented by an ink jet method, but can be used for coating any liquid material, without any particular limitation to ink. Also, media on which the liquid is coated are not limited to paper, but the droplet discharging method may favorably be used to coat liquid on a semiconductor substrate or the like. In addition, by setting in advance the amount of liquid to be coated and the position to be coated, the liquid can be coated in a fine configuration. Therefore, the liquid can be coated locally only along the circumference of the capacitor structure 50, as shown in FIGS. 1 through 3.

The polymer precursor is coated as a liquid having such a degree of flowability that the polymer precursor can be coated by a droplet discharging method. For example, when the protection layer 60 is formed from epoxy resin, a mixture of source materials for the epoxy resin is coated as the polymer precursor. An example of the polymer precursor for the epoxy resin may be a mixture of bisphenol A and diethylene-triamine. This polymer precursor can further include an appropriate solvent, whereby its viscosity can be adjusted to the level suitable for a droplet discharging method.

When the protection layer 60 is formed with thermoplastic resin such as polyethylene, the resin dissolved in solvent forms a polymer precursor. Xylene solution of polyethylene may be enumerated as such a polymer precursor. The density of the resin in the solvent may be changed, thereby adjusting the viscosity of the polymer precursor to be suitably used for a droplet discharging method.

The step of coating the polymer precursor may further include a heat treatment step for heating the polymer precursor. For example, when the protection layer 60 is formed with thermosetting resin, the heat treatment step may be included for promoting the reaction by heating, for drying the solvent of the thermoplastic resin, and the like. According to specific examples, for example, in the case of a polymer precursor including bisphenol A and diethylene-triamine, the reaction may be promoted by heating the material at 80° C. to 120° C. after the material has been coated. In the case where xylene solution of polyethylene is used as a polymer precursor, the solution may be heated at about 80° C., thereby evaporating and removing the solvent, xylene. In either of the examples, a pressure reducing treatment may be performed depending on the necessity.

Also, the coating step may further include a radiation treatment step for applying radiation to a polymer precursor. For example, when the polymer precursor includes a compound that causes a cross-linking reaction by light, such as, a photo polymerization agent, a light treatment step may be included.

The piezoelectric element 100 is manufactured in a manner described above. However, the manufacturing method in accordance with the present embodiment may include a step of forming another member, a surface treatment step and the like between adjacent steps.

According to the method for manufacturing the piezoelectric element 100 in accordance with the present embodiment, a droplet discharging method is used, such that the piezoelectric element 100 can be obtained with a relatively simple process.

3. Reference Example

FIG. 9 is a graph that compares insulation properties of materials that may be used for the protection layer 60. Electric currents are plotted along the axis of ordinates of the graph, and applied voltages are plotted along the axis of abscissas. Samples prepared for the measurement in the reference example had a structure in which a layer of each of the materials having a specified thickness was interposed between electrodes having an area of 0.00031 cm². Then, an electric current generated upon application of a DC voltage across the two electrodes of each of the samples was measured. The measurement voltage was swept from 0V to 80V, changed to 0V again, and then swept to −80V. During this period, the current was measured at intervals of 2V to 5V. The positive and negative states of the voltage indicate, for the sake of convenience, the higher-lower relation between the potentials of the two electrodes.

In FIG. 9, plots indicated by ◯ are measurement results of the sample in which a thermosetting epoxy resin layer of 1100 nm in thickness is interposed between the electrodes. The thermosetting epoxy resin was formed by a droplet discharging method. In FIG. 9, plots indicated by Δ are measurement results of the sample in which a silicon oxide layer of 130 nm in thickness is interposed between the electrodes. The silicon oxide layer was formed by a CVD method, using tetramethoxysilane as a source material. In FIG. 9, plots indicated by □ are measurement results of the sample in which an aluminum oxide layer of 100 nm in thickness is interposed between the electrodes. The aluminum oxide layer was formed by a CVD method, using triethylaluminum as a source material.

As is clear from FIG. 9, the electric currents generated in the sample of thermosetting epoxy resin are lower than 3×10⁻⁹ A in the entire range of applied voltages between −80V and +80V, which indicates very high insulation. In contrast, the electric currents generated in the samples of silicon oxide and aluminum oxide are both over 1×10⁸ A in the regions of applied voltages between +60V and +80V, and −60V and −80V, which indicates low insulation. Also, it is found that the sample of thermosetting epoxy resin had current values smaller in the other of one digit ( 1/10) than that of the samples of silicon oxide and aluminum oxide, which also indicates that the sample of thermosetting epoxy resin has high insulation property.

Thermosetting epoxy resin, one exemplary material for the protection layer 60 in accordance with the present embodiment, has excellent insulation. Therefore, the results of the reference example suggest that, by forming the protection layer 60 from the resin material described above, leakage current of the piezoelectric element can be made smaller.

The invention is not limited to the embodiments described above, and many modifications can be made. For example, the invention may include compositions that are substantially the same as the compositions described in the embodiments (for example, a composition with the same function, method and result, or a composition with the same objects and result). Also, the invention includes compositions in which portions not essential in the compositions described in the embodiments are replaced with others. Also, the invention includes compositions that achieve the same functions and effects or achieve the same objects of those of the compositions described in the embodiments. Furthermore, the invention includes compositions that include publicly known technology added to the compositions described in the embodiments.

What is claimed is:

1. A piezoelectric element comprising:
a base substrate;
a lower electrode provided on the base substrate;
a piezoelectric layer provided on the lower electrode;
an upper electrode provided on the piezoelectric layer; and
a protection layer that covers a side surface of the piezoelectric layer, wherein the protection layer is formed from polymeric material.

2. A piezoelectric element according to claim 1, wherein the polymeric material includes at least one type of thermosetting resin, radiation setting resin, modified product of the thermosetting resin, and modified product of the radiation setting resin.

3. A piezoelectric element according to claim 1, wherein the polymeric material includes one of thermoplastic material and modified product of the thermoplastic material.

4. A method for manufacturing a piezoelectric element comprising the steps of:
forming a lower electrode on a base substrate;
successively laminating a piezoelectric layer and an upper electrode layer on the base substrate and the lower electrode; and
coating a polymer precursor to cover at least an exposed surface of the piezoelectric layer, wherein the step of coating the polymer precursor is performed by a droplet jet method.

5. A method for manufacturing a piezoelectric element according to claim 4, further comprising a heat treatment step of heating the polymer precursor to be changed to a polymeric material.

6. A method for manufacturing a piezoelectric element according to claim 4, further comprising a radiation treatment step of applying radiation to the polymer precursor to be changed to a polymeric material.
